(19) United States
(12) Patent Application Publication
(10) Pub. No.: US 2007/0287072 A1
(43) Pub. Date: Dec. 13, 2007

(54) MASK SUBSTRATE DEPTH ADJUSTMENT TO ADJUST FOR TOPOGRAPHY ON SURFACE

(76) Inventor: Bernhard R. Liegl, Beacon, NY (US)

Correspondence Address: HOFFMAN, WARNICK & D'ALESSANDRO LLC, 75 STATE ST, 14TH FL, ALBANY, NY, 12207, US

(21) Appl. No.: 11/422,612

(22) Filed: Jun. 7, 2006

(51) Int. Cl. G03F 7/26

(52) U.S. Cl. 430/5; 430/30

(57) ABSTRACT

Methods of forming and using a mask having a mask substrate including a non-planar surface are disclosed. The non-planar surface includes at least one portion having a depth configured to compensate for topography on the surface of a semiconductor wafer.

### BACKGROUND OF THE INVENTION

1. Technical Field

The invention relates generally to semiconductor fabrication, and more particularly, to methods of forming and using a mask having a mask substrate including a non-planar surface to adjust for topography on a surface of a wafer.

2. Background Art

In the semiconductor fabrication industry, a process, referred to as photolithography, is used to transfer patterns from a mask (or reticle) to a layer of sacrificial imaging film (i.e., a photoresist) deposited on a surface of a wafer. The photoresist protects or exposes parts of the wafer to further processing. One typical mechanism used to transfer the image is an optical projection system. In order to achieve a satisfactory image of the pattern on the wafer, the imaging focus plane needs to be aligned with the photoresist film across the entire image. If the wafer exhibits significant topography, however, a satisfactory image may not be achieved for the whole image and a loss of pattern fidelity may result. Such topography is frequently the result of a variation of circuit density across the image. In particular, the circuit density variation affects planarization of layers of the wafer during chemical mechanical polishing (CMP), which creates the varying topography.

FIG. 1 shows an across-image topography for a high volume chip after several layers of interconnect processing. The topography has greater than 0.5 μm variation, which exceeds the depth-of-focus for the next imaging cycle. As a result, this topography would prevent obtaining a satisfactory image across the entire wafer. FIG. 2 shows a wafer 10 having a surface 12 with topography 14 in the form of a step or raised area 16. As indicated, a focal plane 18 of an imaging system 20 is appropriate for one part 22 of wafer 10, but not for another part 24, i.e., step 16.

Conventionally, imaging tools attempt to compensate for topography by leveling the wafer below the focal plane in a linear fashion. Unfortunately, this approach does not satisfactorily compensate for all extents of topography that may occur. Other approaches attempt to increase the depth of focus. This approach, however, has limitations.

### SUMMARY OF THE INVENTION

Methods of forming and using a mask having a mask substrate including a non-planar surface are disclosed. The non-planar surface includes at least one portion having a depth configured to compensate for topography on the surface of a semiconductor wafer.

A first aspect of the invention provides a method comprising: adjusting a depth of at least one portion of a mask substrate used to support a template of a mask to adjust a focal plane of an image created by the mask for a positive topography on a surface to be imaged; and using the mask to image the surface.

A second aspect of the invention provides a method of forming a mask comprising: providing a mask substrate for supporting a template that includes a pattern for imaging a surface; adjusting a depth of at least one portion of the mask substrate to adjust a focal plane of an image created using the mask for a topography of the surface; and forming the template, including the pattern, on the mask substrate.

A third aspect of the invention provides a mask for imaging a surface of a wafer, the mask comprising: a template including a pattern to be transferred to a surface of the wafer using the mask; and a mask substrate for supporting the template, the mask substrate having a non-planar surface.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a surface of a wafer according to the prior art.

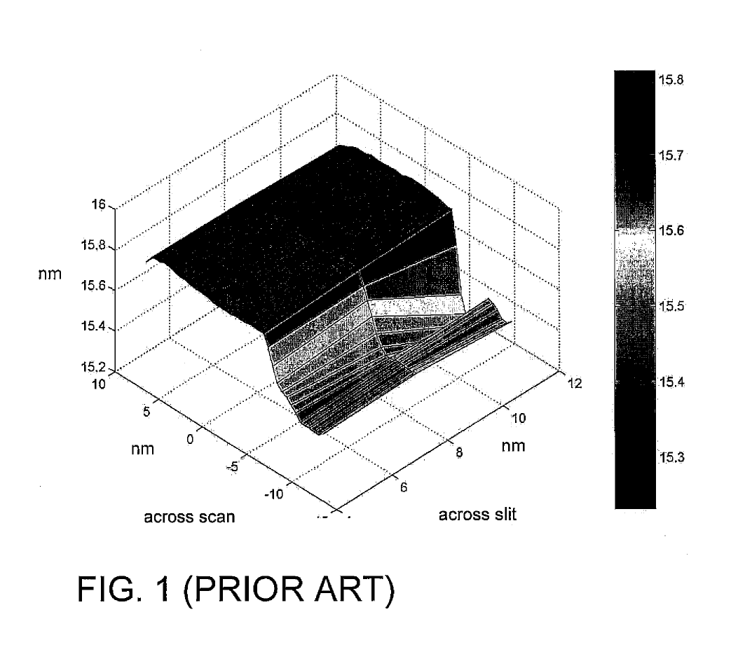

FIG. 2 shows a conventional mask used to image a wafer.

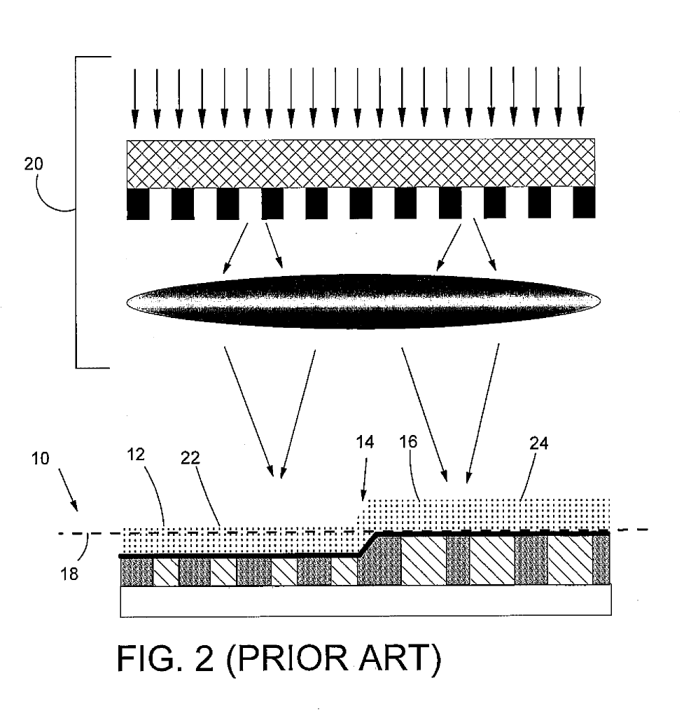

FIG. 3 shows a mask according to one embodiment of the invention.

FIG. 4 shows one embodiment of a method of forming a mask according to the invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

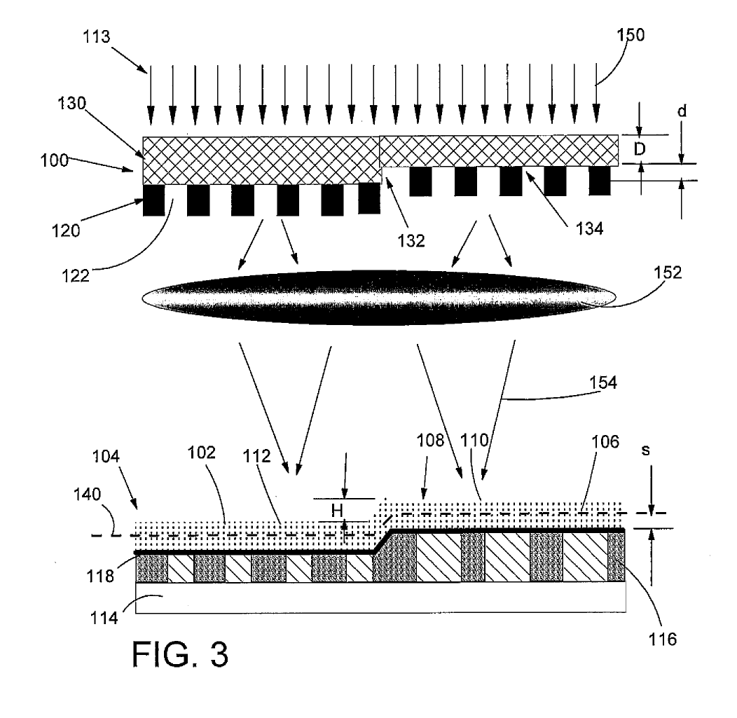

FIG. 3 shows a mask 100 for imaging a surface 102 of a wafer 104. Surface 102 may include any now known or later developed sacrificial imaging film 106 (e.g., photoresist). As shown in FIG. 3, surface 102 includes topography 108 including, for example, a step or raised area 110. Step 110 is referred to as having a “positive topography” because it is raised compared to a lowest most surface portion 112 of surface 102. Step 110 is of a sufficient height (H) that it exceeds the depth-of-focus for an imaging system 113, e.g., an optical imaging system. Wafer 104 may also include a silicon substrate 114, a prior layer 116, e.g., an interlayer dielectric (ILD) with contact vias and/or wiring therein, and an anti-reflective coating (ARC) 118. However, the structure of wafer 104 may vary.

Mask 100 includes a template 120 including a pattern 122 to be transferred to surface 102 of wafer 104 using mask 100. Template 120 may include a chrome, molybdenum silicide (MoSi) and/or other material for forming pattern 122. Pattern 122 may include any shape or formation to generate the required structure on surface 102. Mask 100 also includes a mask substrate 130 for supporting template 120. Mask substrate 130 may include a glass, calcium fluoride and/or other common mask substrate material. As shown in FIG. 3, mask substrate 130 includes a non-planar surface 132. Non-planar surface 132 includes at least one portion 134 having a depth (D) configured to compensate for topography 108 on surface 102. More specifically, mask substrate depth (D) is reduced in portion(s) 134 compared to the rest of mask substrate 130 by a depth (d) that is substantially equal to: d=(n−1)/s*r², where d is the amount of reduced depth, n is a refractive index of mask substrate 130, s is a desired shift in focal plane 140 for topography 108, and r is a reduction factor of a projection imaging system, i.e., one used to image surface 102. The desired shift (s) in focal plane 140 is based on a size of topography 108, i.e., a size of step 110. A correlation between the desired shift (s) in focal plane 140 can be easily determined, for example, through empirical data compared to topography 108 size variations, or by any other now known or later developed mechanism. Any number of portion(s) 134 may be provided on mask 100 to adjust for any number of positive topography 108 issues.

As known in the art, mask 100 may be used to image surface 102, e.g., photoresist 106, by transferring pattern 122 using transmission of light 150 through mask 100, including mask substrate 130 and template 120, through an imaging lens 152 to surface 102. In this fashion, an image 154 is created on surface 102 at a focal plane 140. Focal plane 140, however, changes depending on depth (D) of masking substrate 130. As such, portion(s) 134 can be generated to adjust focal plane 140 to accommodate topography 108. As those skilled in the art will recognize, the wavelength of light 150 may vary depending on a variety of factors.

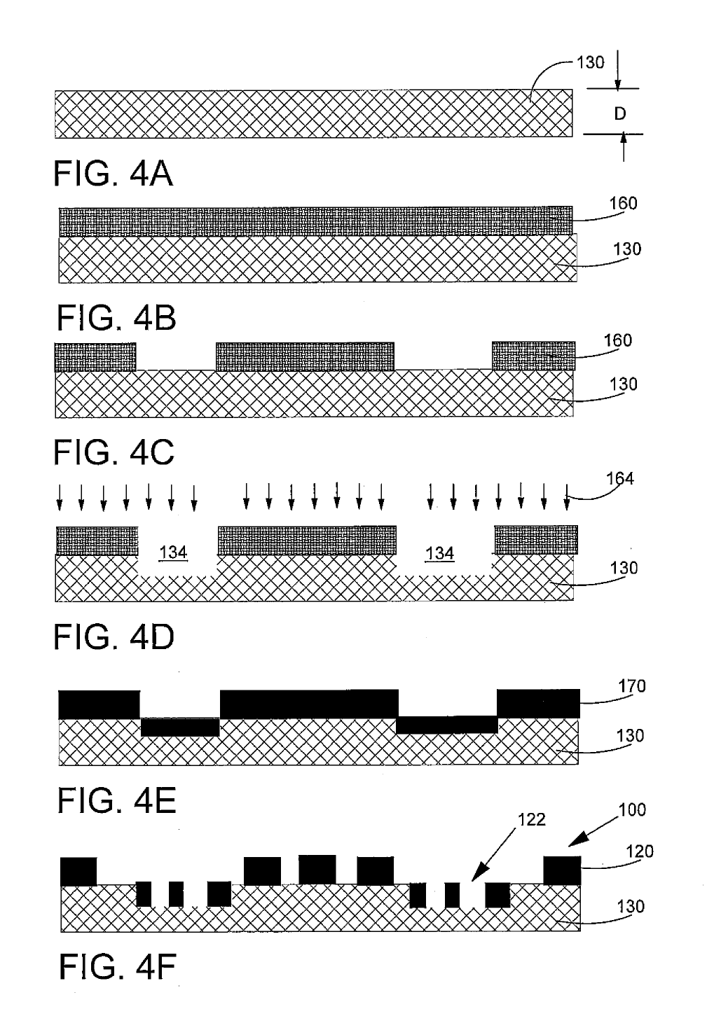

Turning to FIGS. 4A-4F, along with FIG. 3, one embodiment of a method of forming mask 100 is illustrated. In a first step, a depth (D) of at least one portion 134 (FIG. 4C) of mask substrate 130 is adjusted to adjust focal plane 140 of image 154 created by mask 100 for positive topography 108 on surface 102 to be imaged. In one embodiment, this step may include, as shown in FIG. 4A, providing mask substrate 130 for supporting template 120 without template 120. As will be described below, template 120 will eventually be provided and will include pattern 122 (FIG. 3) for imaging surface 102.

Next, as shown in FIGS. 4B-4C, depth (D) of at least one portion 134 (FIG. 3) of mask substrate 130 is adjusted to adjust focal plane 140 (FIG. 3) of image 154 created using mask 100 for topography 108 of surface 102. In one embodiment, this depth adjustment may be generated by etching back mask substrate 130 to adjust focal plane 140 (FIG. 3) of image 154 (FIG. 3) for positive topography 108. This step may further include determining a topography of the surface including height variation (H) of topography 108 such that a desired depth adjustment (d) can be determined. This step may be implemented by forming a photoresist 160 (FIG. 4B), patterning photoresist 160 (FIG. 4C), etching 164 mask substrate 130 to form portion(s) 134, and then removing photoresist 160 (not shown). Etching back may include etching back by a depth (d), as described above. Etching 164 may use any appropriate etch chemistry for the material used for mask substrate 130. For example, for chrome-on-glass, etching 164 may use a chlorine-oxygen (Cl₂/O₂) reactive ion etch (RIE) chemistry, and for molybdenum silicide, etching 164 may use a sulfur hexafluoride and helium (SF₆/He) RIE chemistry. Other etch chemistries may also be used. It is understood that adjustment of depth (D) may also be created by addition of material to mask substrate 130.

Next, as shown in FIG. 4E-F, mask 100 is formed using mask substrate 130 and template 120. That is, template 120 (FIG. 4F), including pattern 122, is formed on mask substrate 130. This step may include forming a template material layer 170, e.g., chrome, on mask substrate 130, which would include forming layer 170 across portion(s) 134. Template 120 including pattern 122 would then be formed by patterning a photoresist (not shown) thereon, etching to create pattern 122 and then removing the photoresist to arrive at mask 100 (FIG. 4F).

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A method comprising:
adjusting a depth of at least one portion of a mask substrate used to support a template of a mask to adjust a focal plane of an image created by the mask for a positive topography on a surface to be imaged; and
using the mask to image the surface.

2. The method of claim 1, wherein the adjusting includes:
providing the mask substrate;
determining a topography of the surface;
etching back the mask substrate in the at least one portion to adjust the focal plane of the image for the positive topography;
forming the mask using the etched back mask substrate and the template.

3. The method of claim 2, wherein the etching back includes etching to a depth substantially equal to:
d=(n−1)/s*r²,
where d is the depth, n is a refractive index of the mask substrate, s is a desired shift in the focal plane and r is a reduction factor of a projection imaging system used to image the surface.

4. The method of claim 3, wherein the desired shift in the focal plane is based on a size of the positive topography.

5. The method of claim 1, wherein the mask substrate includes at least one of the following: a glass and calcium fluoride.

6. The method of claim 1, wherein the template includes at least one of the following: a chrome and molybdenum silicide.

7. The method of claim 1, wherein the using step includes transmitting light through the mask substrate and the template and through an imaging lens to the surface of the wafer.

8. A method of forming a mask comprising:
providing a mask substrate for supporting a template that includes a pattern for imaging a surface;
adjusting a depth of at least one portion of the mask substrate to adjust a focal plane of an image created using the mask for a topography of the surface; and
forming the template, including the pattern, on the mask substrate.

9. The method of claim 8, wherein the adjusting includes:
determining a topography of the surface; and
etching back the mask substrate in the at least one portion to adjust the focal plane of the image for the topography.

10. The method of claim 9, wherein the etching back includes etching to a depth substantially equal to:
d=(n−1)/s*r²,
where d is the depth, n is a refractive index of the mask substrate, s is a desired shift in the focal plane and r is a reduction factor of a projection imaging system used to image the surface.

11. The method of claim 10, wherein the desired shift in the focal plane is based on a size of the topography.

12. The method of claim 9, wherein the mask substrate includes at least one of the following: a glass and calcium fluoride.

13. The method of claim 9, wherein the template includes at least one of the following: a chrome and molybdenum silicide.

14. A mask for imaging a surface of a wafer, the mask comprising:
a template including a pattern to be transferred to a surface of the wafer using the mask; and
a mask substrate for supporting the template, the mask substrate having a non-planar surface.

15. The mask of claim 14, wherein the non-planar surface includes at least one portion having a depth configured to compensate for a topography on the surface of the wafer.

16. The mask of claim 15, wherein the depth is reduced compared to a remainder of the mask substrate by an amount substantially equal to:
d=(n−1)/s*r²,
where d is the depth, n is a refractive index of the mask substrate, s is a desired shift in the focal plane and r is a reduction factor of a projection imaging system used to image the surface.

17. The mask of claim 16, wherein the desired shift in the focal plane is based on a size of the topography.

18. The mask of claim 14, wherein the mask substrate includes at least one of the following: a glass and calcium fluoride.

19. The mask of claim 14, wherein the template includes at least one of the following: a chrome and molybdenum silicide.
